(19) United States
(12) Patent Application Publication
(10) Pub. No.: US 2026/0107579 A1
(43) Pub. Date: Apr. 16, 2026

(54) HETEROJUNCTION BIPOLAR TRANSISTOR

(71) Applicant: GlobalFoundries U.S. Inc., Malta, NY (US)

(72) Inventors: Aaron Lee Vallett, Jericho, VT (US); Steven M. Shank, Jericho, VT (US); Uppili Srinivasan Raghunathan, Essex Junction, VT (US); Vibhor Jain, Clifton Park, NY (US); John Joseph Ellis-Monaghan, Grand Isle, VT (US)

(21) Appl. No.: 18/916,526

(22) Filed: Oct. 15, 2024

(51) Int. Cl. H01L 27/12; H01L 21/8249; H01L 29/10; H01L 29/161; H01L 29/737; H01L 29/78

(52) U.S. Cl. CPC H10D 87/00; H10D 10/821; H10D 62/177; H10D 84/0109; H10D 84/038; H10D 30/60; H10D 62/832

(57) ABSTRACT

The present disclosure relates to semiconductor structures and, more particularly, to a heterojunction bipolar transistor and methods of manufacture. The structure includes: a plurality of active devices in a layout, the plurality of active devices comprising semiconductor material with a first dopant type; a protective film; and a fill shape covering the protective film and comprising the semiconductor material with the first dopant type.

### BACKGROUND

The present disclosure relates to semiconductor structures and, more particularly, to a heterojunction bipolar transistor and methods of manufacture.

A heterojunction bipolar transistor (HBT) is a type of bipolar junction transistor (BJT) that uses different semiconductor materials for the emitter and base regions, creating a heterojunction. The HBT can handle signals of very high frequencies, up to several hundred GHz. The HBT can be used, for example, in radio frequency (RF) systems, and in applications requiring a high power efficiency, such as RF power amplifiers in cellular phones.

### SUMMARY

In an aspect of the disclosure, a structure comprises: a plurality of bipolar devices in a layout, the plurality of active devices comprising semiconductor material with a first dopant type; a protective film; and a fill shape covering the protective film and comprising the semiconductor material with the first dopant type.

In an aspect of the disclosure, a structure comprises: a plurality of active devices formed on a semiconductor substrate, the plurality of active devices comprising at least a top semiconductor material with a first dopant type; a protective film on a same level and adjacent to the plurality of active devices; and a fill shape covering comprising the top semiconductor material with the first dopant type.

In an aspect of the disclosure, a method comprises: forming a plurality of active bipolar devices in a layout, the plurality of active bipolar devices comprising semiconductor material with a first dopant type; forming a fill shape covering a protective film and comprising the semiconductor material with the first dopant type.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a device layout and respective fabrication processes in accordance with aspects of the present disclosure.

FIG. 2 shows a cross-sectional view of a fill shape over a shallow trench isolation region and respective fabrication processes in accordance with aspects of the present invention.

FIG. 3 shows fill shapes over the shallow trench isolation region and a fill shape of active material (RX) and respective fabrication processes in accordance with aspects of the present disclosure.

FIG. 4 shows a fill shape used with a contact and respective fabrication processes in accordance with aspects of the present disclosure.

FIG. 5 shows a fill shape adjacent to a contact and over an active material (RX) and respective fabrication processes in accordance with aspects of the present disclosure.

### DETAILED DESCRIPTION

The present disclosure relates to semiconductor structures and, more particularly, to a heterojunction bipolar transistor and methods of manufacture. More specifically, the present disclosure relates to fill shapes used in combination with heterojunction bipolar transistors (HBT) in a BiCMOS technology that also contains field effect transistors (FET). In embodiments, by using the fill shapes, the transistors (e.g., FETs) will not exhibit significant device shifts due to dopant penetration from gate polysilicon into the channel region caused by trapped hydrogen in a protective film. Advantageously, the fill shapes described herein will reduce FET bipolar proximity effect with no increase in CMOS area or cost, in addition to improving cross-chip uniformity during HBT etching.

In more specific embodiments, a logic layout in BiCMOS processes and, more specifically, SiGe BiCMOS processes, may include HBT based fill shapes that open a cavity in overlying protective films. For example, in embodiments, white space and/or well contacts in the logic layout may include fill shapes comprising bipolar transistor materials. In further embodiments, the fill shapes may be above an active layer (RX layer) and/or above shallow trench isolation structures. The bipolar layers may be, for example, SiGe or Si or combinations thereof doped with boron or arsenic or carbon, etc. and which are also used for the fabrication of an NPN device or PNP device or a diode.

By implementing the use of the fill shapes, it is possible to reduce or eliminate dopant penetration for example boron that may occur during bipolar transistor formation. This, in turn, will reduce significant device shifts due to dopant penetration from gate polysilicon into a channel region caused by trapped hydrogen in the overlying protective film, e.g., nitride film. As should be understood by those of skill in the art, in conventional processes, dopant penetration from the gate polysilicon may vary with proximity to the bipolar devices as a nitride film (or other masking material) is opened for bipolar formation.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

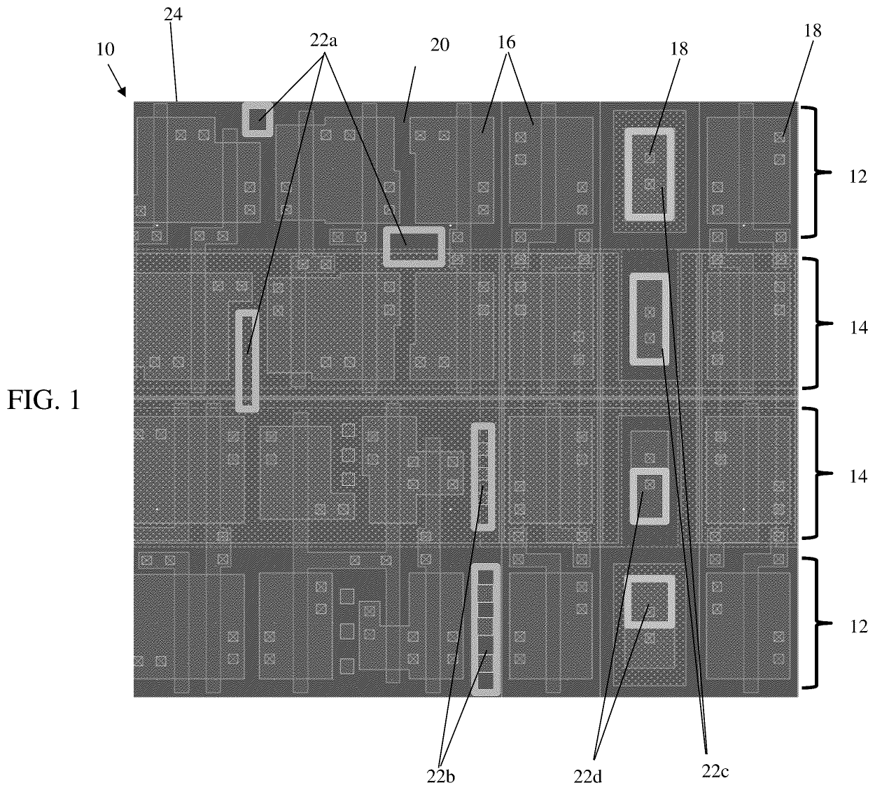

FIG. 1 shows a layout with fill shapes in accordance with aspects of the present disclosure. In the layout 10 of FIG. 1, NFETs in a p-well are represented by reference numeral 12 and PFETs in an n-well are represented by reference numeral 14. The NFETs and PFETs are provided in active regions 16. In embodiments, semiconductor substrate 24 of the active regions 16 may be any semiconductor material, e.g., Si, SiGe, SiGeC, SiC, GaAs, InAs, InP, and other III/V or II/VI compound semiconductors. The semiconductor substrate 24 of the active regions 16 may be semiconductor on insulator (SOI) technologies or bulk substrate as known in the art. The semiconductor material of the active region 16 is preferably any suitable crystallographic orientation (e.g., a (100), (110), (111), or (001) crystallographic orientation). In embodiments, the insulator material in the SOI technologies may comprise any suitable material, including silicon oxide, sapphire, other suitable insulating materials, and/or combinations thereof. An exemplary insulator layer may be a buried oxide layer (BOX).

FIG. 1 further shows contacts 18 provided in the active regions 16 and connecting to the NFETs and PFETs as is well known in the art such that no further explanation is required for a complete understanding of the present disclosure. Shallow trench isolation structures 20 may be provided to isolate the different devices, e.g., NFETs and PFETs, and other structures as is known in the art. The shallow trench isolation structures can be formed by conventional lithography, etching and deposition methods known to those of skill in the art and as further described herein.

Although not shown, silicide contacts may be provided on the active regions 16, prior to the formation of the contacts 20. As should be understood by those of skill in the art, the silicide process begins with deposition of a thin transition metal layer, e.g., nickel, cobalt or titanium, over fully formed and patterned semiconductor devices (e.g., doped or ion implanted source and drain regions and respective devices). After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts in the active regions 16 of the device.

FIG. 1 further shows fill shapes 22a, 22b, 22c, 22d interspersed throughout the layout 10, adjacent to the active regions 16 or other structures described herein. In embodiments, the fill shapes 22a, 22b, 22c, 22d are dummy fill shapes, e.g., are not active devices. For example, although the fill shapes 22a, 22b, 22c, 22d may comprise the same semiconductor material used in the fabrication of the active devices, as described in more detail herein, the placement and/or location of the fill shapes 22a, 22b, 22c, 22d will result in dummy structures. In embodiments, the fill shapes can prevent dopant penetration into a channel region of the active device, e.g., FET.

In embodiments, the fill shapes 22a, 22b, 22c, 22d may be a minimum required distance from the devices, e.g., NFETs or PFETs, and may include different materials depending on whether they are used in the formation of an NPN device or PNP device as further described herein. Also, as should be understood by those of skill in the art, the present disclosure contemplates other locations of the fill shapes 22a, 22b, 22c, 22d in any combination interspersed in the layout to provide the advantages described herein.

By way of non-limiting examples, the fill shapes 22a may be over a shallow trench isolation structure 20 adjacent to the active devices (e.g., NFET or PFET devices). Moreover, the fill shapes 22b may be over shallow trench isolation structures 20 and semiconductor substrate 24 (e.g., Rx layer or white space) (adjacent to the active devices), the fill shapes 22c may be over contact regions (thereby acting as contacts), and the fill shape 22d may be adjacent to the contacts 18. In addition, any of the fill shapes may be partially over white space or, alternatively, partially over the shallow trench isolation structures or, alternatively, partially over or adjacent to the contact region, or, alternatively, combinations thereof.

In embodiments, the fill shapes 22a, 22b, 22c, 22d may be provided within a cavity formed from etching of a protective underlying film, e.g., nitride film that is on a same level as the active devices, used in the fabrication of the active devices. The material of the fill shapes 22a, 22b, 22c, 22d may use the same materials as the bipolar transistors, e.g., NPNs or PNPs, or a diode. For example, the material of the fill shapes may be SiGe or Si doped with boron or arsenic or carbon or other n-type or p-type dopants depending on the location of the fill shapes with respect to the NPN or PNP.

Also, the fill shapes 22a, 22b, 22c, 22d may maintain a minimum distance and density to the FETs, e.g., 1-50 μm.

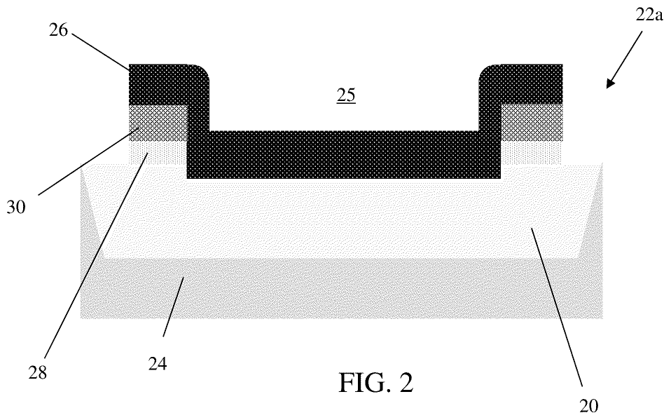

FIG. 2 shows a cross-sectional view of a fill shape and respective fabrication processes in accordance with aspects of the present invention. In this embodiment, the fill shape 22a may be located over a shallow trench isolation structure 20 (adjacent to a gate structure of either a PFET device or NFET device).

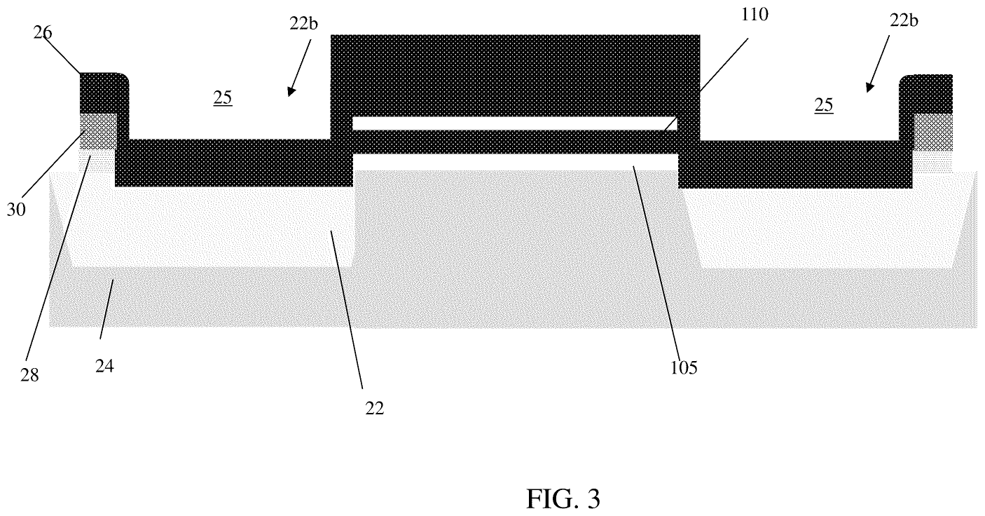

In embodiments, the fill shape 22a may be formed within a cavity 25 of an underlying insulator material 28 (e.g., oxide material which may be part of a protective film stack) and a protective film 30 used in the formation of the active devices. In embodiments, the material 26 of the fill shape 22a is over the shallow trench isolation structure 20 and extends over the protective film 30 and the underlying buried insulator material 28. And as further described with respect to FIG. 3, the material 26 of the fill shape 22b is provided over the semiconductor material of the active device, e.g., NPN or PNP.

In embodiments, the protective film 30 may be a nitride film which includes trapped hydrogen. The nitride film may be provided on a same level as the active device, e.g., PFET and/or NFET. As shown in FIG. 2, for example, boron penetration into the channel region of the FET device can now be avoided due to formation of the fill shape 22b in the cavity 25, adjacent to the channel region of the device. For example, the etching process to form the cavity 25 effectively removes the protective film 30 from near the channel region of the FET device and, hence, trapped hydrogen would not escape during an epitaxial growth process resulting in boron penetrating into the channel region of the PFET device. It should be understood that a portion of the protective film 30 may remain near the channel region of the FET, but this is only small portion which should not result in any significant dopant penetration into the channel region as described herein.

Referring still to FIG. 2, in embodiments, the material 26 of the fill shape 22b may comprise semiconductor material deposited by a conventional deposition process, e.g., chemical vapor deposition (CVD), over the shallow trench isolation structures 22 and the protective film 30. As should be understood by those of skill in the art, deposition of the semiconductor substrate 24 over the shallow trench isolation structures 22 will result in the formation of polysilicon or amorphous semiconductor material (compared to single crystalline when formed directly on the underlying semiconductor substrate 24). In embodiments, the semiconductor material 26 may be SiGe material, which is also used as an extrinsic base for an NPN device or PNP device. In alternative embodiments, the semiconductor material 26 may be Si doped with n-type dopants, e.g., Arsenic (As), Phosphorus (P) and Antimony (Sb), which is also used as an extrinsic base for the PNP device.

The cavity 25 may be formed by conventional lithography and etching processes as is known in the art. Also, the shallow trench isolation structure 22 may be formed in an underlying semiconductor substrate 24 by conventional lithography, etching and deposition methods known to those of skill in the art. For example, as to the formation of the shallow trench isolation structure 22, a resist formed over the semiconductor substrate 24 is exposed to energy (light) and developed utilizing a conventional resist developer to form a pattern (opening). An etching process with a selective chemistry, e.g., reactive ion etching (RIE), will be used to transfer the pattern from the photoresist layer to the semiconductor substrate 24 to form one or more trenches in the semiconductor substrate 24. Following the resist removal by a conventional oxygen ashing process or other known stripants, insulator material (e.g., oxide based material) can be deposited by any conventional deposition processes, e.g., CVD processes. Any residual material on the surface of the semiconductor substrate 24 can be removed by conventional chemical mechanical polishing (CMP) processes. The cavity 25 may be formed in a similar manner by patterning the underlying insulator material 28 and protective film 30.

FIG. 3 shows the fill shapes 22b which may be adjacent to an active device, e.g., FET (not shown), in accordance with aspects of the present disclosure. Part of the fill shape 22b may be raised over an active semiconductor substrate 24. As noted above, the fill shape 22b may be within a cavity 25 and comprises semiconductor material 26 that is used in the active device. The semiconductor material 26 may be provided over the protective film 30, e.g., nitride, and a buried insulator 20. The fill shape 22b is also recessed with respect to the active device. That is, the fill shape 22b has an upper surface that is lower relative to the active device. In embodiments, the fill shape 22b may be provided over a shallow trench isolation structure 24 (which in embodiments may be on a side of an active device), in addition to being a top layer of the active device.

Still referring to FIG. 3, the material used in the fill shapes 22b may include SiGe material 110 over a semiconductor material 105. The SiGe material 110 may also be used as a base of an active device and the semiconductor material 105 may also act as a collector region of an active device. The underlying semiconductor substrate 24 may be a sub-collector region (e.g., a p-well for an NPN device and an n-well for a PNP device). Both the SiGe material 110 and semiconductor material 105 may be epitaxially grown directly on the underlying semiconductor substrate 24.

Although the active device is not shown in FIG. 3, it should be understood by those of skill in the art, for an NPN device, the SiGe material 110 may be a p-type material, e.g., doped with boron. Also, for a PNP device, the SiGe material 110 may be an n-type material, e.g., doped with arsenic. In either scenario, the SiGe material 110 may be epitaxially grown with an in-situ doping process. It should be understood by those of ordinary skill in the art that the SiGe material 110 may be other semiconductor materials used in NPN or PNP devices. The semiconductor material 26 may be provided on or over the SiGe material 110.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used. A dopant (n-type or p-type, as defined below) is typically added to the precursor gas or gas mixture.

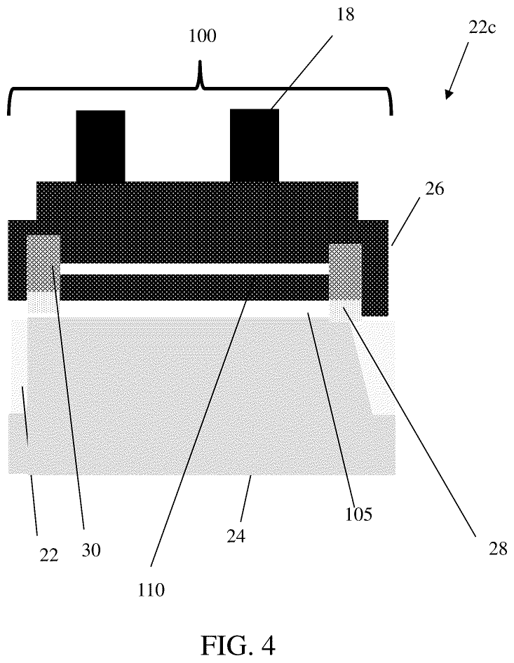

FIG. 4 shows a fill shape used as an n-well contact or p-well contact in accordance with aspects of the present disclosure. As noted above, the fill shape 22c may use films from the NPN device or PNP device. In the NPN device, for example, the semiconductor material 26 of the fill shape 22c may be SiGe material; whereas in the PNP device, for example, the semiconductor material 26 may be Si material. In more specific embodiments, the semiconductor material 26 for the NPN device may be p-doped SiGe and for the PNP device it may be n-doped Si. Accordingly, the fill shape 22c may make use of the same films of the NPN device or PNP device, but will be the well contacts.

As shown in FIG. 4, the semiconductor material 26 is directly over the well connection of an active device 100. Contacts 18 are provided on the semiconductor material 26. As already noted, a silicide contact may be provided on the semiconductor material 26, prior to the formation of the contact 18. In this implementation (and others), the buried insulator material 28 and the protective film 30 may be adjacent to the active device 100.

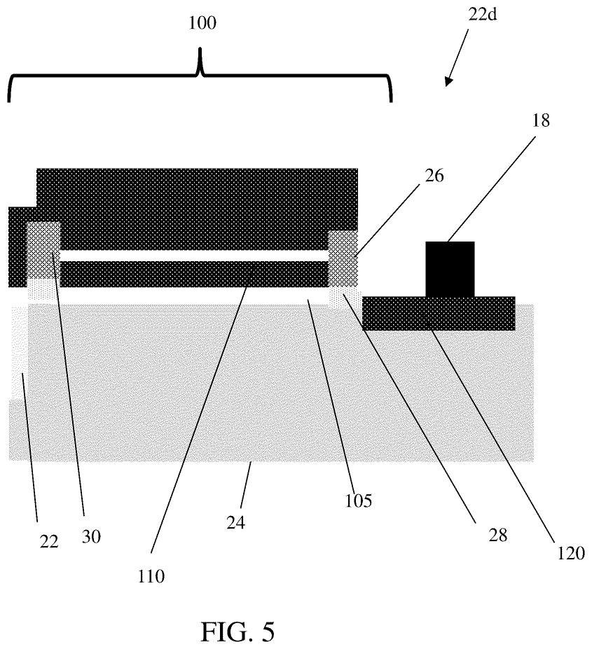

FIG. 5 shows a fill shape used as a well contact 100. The contact 18 may be provided to a P+ implant region 120 in the semiconductor substrate 24. In this embodiment, the material 26 of the fill shape does not extend to or contact the P+ implant region 120. Alternatively, the P+ implant region may be representative of the fill shape material and, hence, the fill shape material can be used for well contacts.

In embodiments, the P+ implant region 120 (in addition to any wells in the semiconductor substrate 24) may be formed by introducing a dopant by, for example, ion implantation in the semiconductor substrate 24. In embodiments, respective patterned implantation masks may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The P+ implant region 120 is doped with p-type dopants, e.g., Boron (B), and an N-well or N+ implant regions are doped with n-type dopants, e.g., Arsenic (As), Phosphorus (P) and Antimony (Sb), among other suitable examples.

The SiGe BiCMOS can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a plurality of active devices in a layout, the plurality of active devices comprising semiconductor material with a first dopant type;
a protective film; and
a fill shape covering the protective film and comprising the semiconductor material with the first dopant type.

2. The structure of claim 1, wherein the protective film comprises a nitride material.

3. The structure of claim 2, wherein the semiconductor material of the plurality of active devices and the fill shape comprises SiGe material.

4. The structure of claim 3, wherein the SiGe material comprises p-type SiGe material.

5. The structure of claim 1, wherein the fill shape is within a cavity above a shallow trench isolation structure and adjacent to the plurality of active devices.

6. The structure of claim 5, wherein the fill shape is adjacent to a channel region of the plurality of active devices.

7. The structure of claim 1, wherein the plurality of active devices comprises one of PFET devices and bipolar devices.

8. The structure of claim 1, wherein the semiconductor material of the fill shape is an extrinsic base of the plurality of active devices.

9. The structure of claim 8, further comprising contacts extending to and contacting the semiconductor material.

10. The structure of claim 1, wherein the fill shapes are placed on a semiconductor substrate.

11. The structure of claim 1, wherein the fill shapes are contacted as a well contact.

12. A structure comprising:
a plurality of active devices formed on a semiconductor substrate, the plurality of active devices comprising at least a top semiconductor material with a first dopant type;
a protective film on a same level and adjacent to the plurality of active devices; and
a fill shape covering comprising the top semiconductor material with the first dopant type.

13. The structure of claim 12, wherein the protective film comprises a nitride material and the plurality of active devices comprise PFETs.

14. The structure of claim 12, wherein the top semiconductor material comprises p-type SiGe material.

15. The structure of claim 12, wherein the top semiconductor material comprises an extrinsic base material of the plurality of active devices.

16. The structure of claim 12, wherein the fill shape is within a cavity above a shallow trench isolation structure and adjacent to the plurality of active devices.

17. The structure of claim 12, wherein the fill shape is adjacent to a channel region of the plurality of active devices.

18. The structure of claim 12, further comprising contacts extending to and contacting the semiconductor material which is above the plurality of active devices.

19. The structure of claim 12, wherein the fill shapes are contacted as a well contact.

20. A method comprises:
forming a plurality of active bipolar devices in a layout, the plurality of active bipolar devices comprising semiconductor material with a first dopant type; and
forming a fill shape covering a protective film and comprising the semiconductor material with the first dopant type.
